(19) United States
(12) Patent Application Publication
(10) Pub. No.: US 2011/0001227 A1
(43) Pub. Date: Jan. 6, 2011

(54) Semiconductor Chip Secured to Leadframe by Friction

(75) Inventor: Kazuaki Ano, Oita (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/792,519

(22) Filed: Jun. 2, 2010

Related U.S. Application Data
(60) Provisional application No. 61/222,339, filed on Jul. 1, 2009.

(51) Int. Cl. H01L 23/495; H01L 21/50; H01R 43/00

(52) U.S. Cl. 257/676; 438/123; 29/825; 257/E21.499; 257/E23.031

(57) ABSTRACT

A semiconductor device (100) with two leads (103) of a leadframe (101) extending from opposite directions towards each other, the leads having tips (103b) curled as springs acting to exert pressure force in the direction of the leads, the two curls spaced apart by a distance operable to secure a semiconductor chip; device (100) further has a semiconductor chip (110) with width (115) and sidewalls (112) clamped in the distance between the two curls, the chip secured to the leadframe by the friction based on the pressure force of the curls.

### FIELD OF THE INVENTION

The present invention is related in general to the field of semiconductor devices and processes, and more specifically to the structure and fabrication method of chip attachment to leadframes secured by friction.

### DESCRIPTION OF RELATED ART

When semiconductor chips have to be attached to carriers, substrates or leadframes, it is common practice to use a layer of adhesive compound, such as an epoxy-based polymeric formulation, as a coupler between the chip and the carrier/substrate. The polymeric compound is usually an adhesive thermoset resin, applied to the chip attach pad of the carrier/substrate as a low-viscosity precursor to allow spreading of the compound over the attach pad. After the precursor resin is distributed, the chip is pressed onto the layer with a force sufficient to partially redistribute the adhesive by flowing and thus to ensure a uniform layer thickness across the whole chip area. Thereafter, the layer, together with the chip and the carrier/substrate, is subjected to elevated temperatures for a certain amount of time to activate a resin polymerization process, which hardens the compound and thus permanently couples chip and carrier/substrate together.

For electrical circuit operation as well as for removal of the operational heat, it is common practice to add to the adhesive compound filler particles, which are electrically and thermally conductive. The most frequently used filler particles are elongated silver flakes with a length between 1 and 10 μm and an approximately uniform distribution across the attach layer. To achieve good electrical and thermal conductivity, the filler loadings typically have to be high, usually more than 80 weight % of the attach compound. The polymeric formulations aim at maximizing mechanical adhesion in spite of high filler loadings.

In some semiconductor devices, the adhesive resin layer is replaced by a metallic layer made either of a tin-based solder, for instance tin-silver, or a eutectic gold/germanium alloy with 12.5 weight % germanium. After attaching and electrically bonding the semiconductor chip to the substrate or leadframe, the assembled device is packaged in a housing made of a polymerized plastic compound.

Thereafter, the encapsulated semiconductor devices are subjected to a series of reliability tests, which have been developed and standardized as accelerated life tests. Each reliability test is sensitive to one or more recognized failure mechanisms, which the test intends to accelerate under aggravated environmental conditions. Frequently observed fallouts include: failure by delamination of contiguous device portions, cracking of the package, and fatigue of solder contacts after 1000 temperature cycles from −40 to +125° C.; failure by corrosion of metallic constituents after 500 hours of operations in 100% humidity and under electrical bias; and failure by losing electrical contacts after 1000 free-fall drops from 1 m heights.

### SUMMARY OF THE INVENTION

A

Applicant discovered, through analyzing plastic packaged semiconductor devices that had failed in temperature cycling and moisture reliability tests, that water molecules penetrating into, and absorbed by, the polymeric attachment and encapsulation compounds is the root cause of the delamination of the chips from the pads and the pads from the package, as well as of the package cracks. Applicant also identified that the difference of the coefficients of thermal expansion (CTE) between the metal pads and the silicon is an additional contributor to the failures.

Applicant observed that the effort in developing improved polymeric formulations of the chip attach and encapsulation compounds for reducing failures, at least so far, has led to unsatisfactory results. And the replacement of the polymeric chip attach compounds with metallic eutectic alloys (such as the gold/germanium alloy with 12.5 weight % germanium) only introduces different failure mechanisms, such as chip cracking.

Applicant solved the delamination problems by eliminating the polymeric attach compound and the metal pad and, instead, using an all-metal leadframe to secure the chip with friction forces applied by metallic leads to opposite side wall surface areas of the chip.

The leads that grip the chip are grouped in pairs from opposite directions. The tip of each lead may be pressed into the shape of a curl varying from about a quarter circle to half circle or full circle. The curls of each pair are spaced apart by a distance operable to secure a semiconductor chip. The curls act as elastic springs when contacting opposite side surfaces of the chip hexahedron to secure the chip by friction.

The process flow of leadframe fabrication and the flow of chip assembly are batch production techniques. Consequently, the preparation of the leadframe as well as the process of assembly of simply inserting the chips into the respective spaces between facing curls are low cost—a clear competitive advantage in the semiconductor industry.

### BRIEF DESCRIPTION OF THE DRAWINGS

FIG. 1 is a schematic cross section of a wire-bonded and packaged semiconductor device, in which the chip is secured to the leadframe by friction; the device is free of a chip attachment pad and an adhesive die attachment compound.

FIGS. 2 to 7 illustrate schematically certain process steps according to an embodiment of the invention for fabricating a leadframe to secure a semiconductor chip to the leadframe by friction, and for fabricating a packaged semiconductor device using this leadframe.

FIG. 2 is a top view depicting a planar leadframe with a first set of leads and a central portion; the leads extend from the frame towards the central portion.

FIG. 3 is a top view depicting the first set of leads and a second set of leads by removing sections of the central portion; the second set leads are grouped in pairs of opposite direction with the tips facing each other.

FIG. 4 is a top view illustrating the curling of the tips of each lead pair in a direction normal to the planar leads; the curls mirror-image each other.

FIG. 5A shows a schematic cross section of the curls for an embodiment wherein the first and the second set leads are in a single plane.

FIG. 5B shows a schematic cross section of the curls for another embodiment wherein the first set leads and the second set leads are in different planes, accomplished by inserting into the pad straps a step from the first to the second plane.

FIG. 6 is a schematic cross section illustrating the process step of inserting a semiconductor chip between the curled tips of opposite leads of the single-plane leadframe of FIG. 5A, thereby securing the chip to the leadframe by friction based on the pressure force of the curled lead tips.

FIG. 7 is a schematic cross section of a wire-bonded and packaged semiconductor device as assembled in FIG. 6; the chip is secured to the leadframe by friction and the device is consequently free of a chip attachment pad and an adhesive attachment compound.

FIG. 8 depicts a top view of a portion of an actual leadframe strip including a plurality of discrete units with second set leads formed similar to the embodiment shown in FIGS. 4 and 5A.

FIG. 9 is an enlargement of a leadframe unit of the strip of FIG. 8, including side views of bent and curled leads of the second set.

FIGS. 10 to 12 illustrate schematically certain process steps according to another embodiment of the invention for fabricating a leadframe to secure a semiconductor chip to the leadframe by friction,

FIG. 10 is a top view depicting a planar leadframe with a first set of leads, a central portion, and a second set of leads extending away from the central portion and grouped in pairs of opposite direction with the tips facing away in opposite directions.

FIG. 11 is a top view illustrating the curling of the tips of each lead pair in opposite clock directions towards the central portion.

FIG. 12 shows a schematic cross section of completed almost full-circle curls operable as springs; the central portion is retained as a flat metal sheet.

### DETAILED DESCRIPTION OF THE PREFERRED EMBODIMENTS

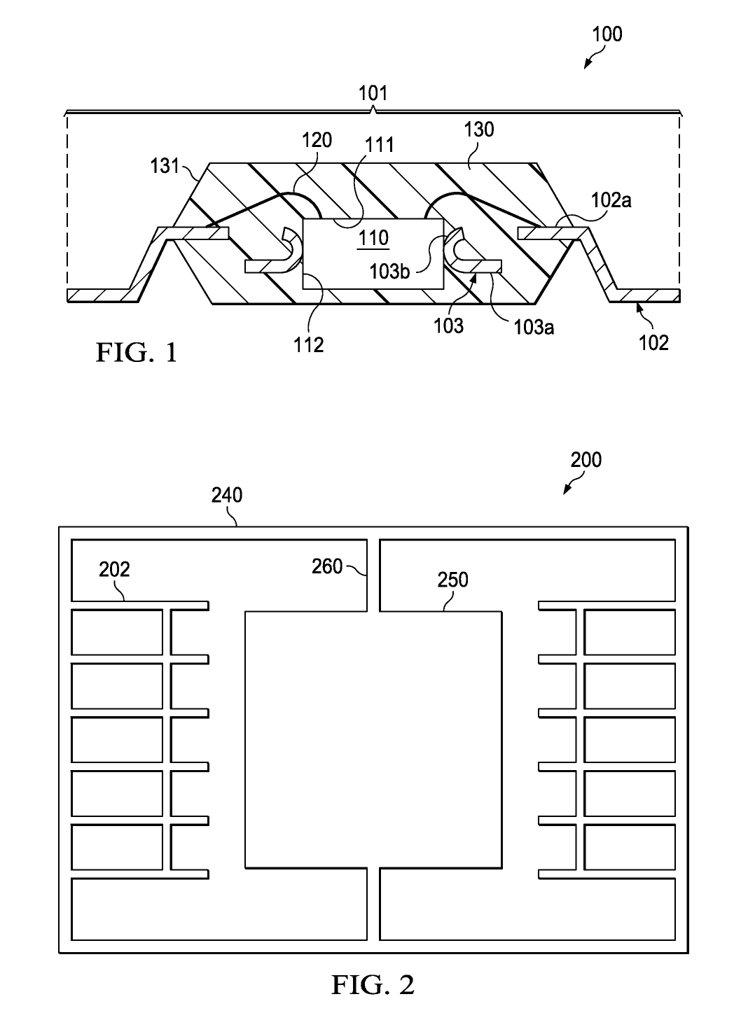

FIG. 1 illustrates an exemplary semiconductor device, generally designated 100, incorporating an embodiment of the invention. Device 100 includes a metal leadframe 101 extending across the outline of device 100, a semiconductor chip 110, electrical conductors 120 (shown as bonding wires) connecting the terminals of chip 110 to leadframe 101, and an insulating encapsulation compound 130 (shown as polymeric molding compound) providing the package 131 of the device.

FIG. 1 shows that metal leadframe 101 includes a first set of leads 102, which provide the electrical connections from the device and the chip inside the package to external circuitry. As an example, the shape of leads 102 may be formed so that leads 102 can be soldered to a printed circuit board; other devices may have leads 102 shaped in different fashion. The portions 102a of leads 102 inside the package 131 are flat and are in a first horizontal plane. As FIG. 1 shows, attached to lead portions 102a are the electrical connections 120 from the lead portions to the chip terminals. FIG. 1 depicts chip 110 in a central region of device 100; in other devices, the chip may be placed in a different region of the device.

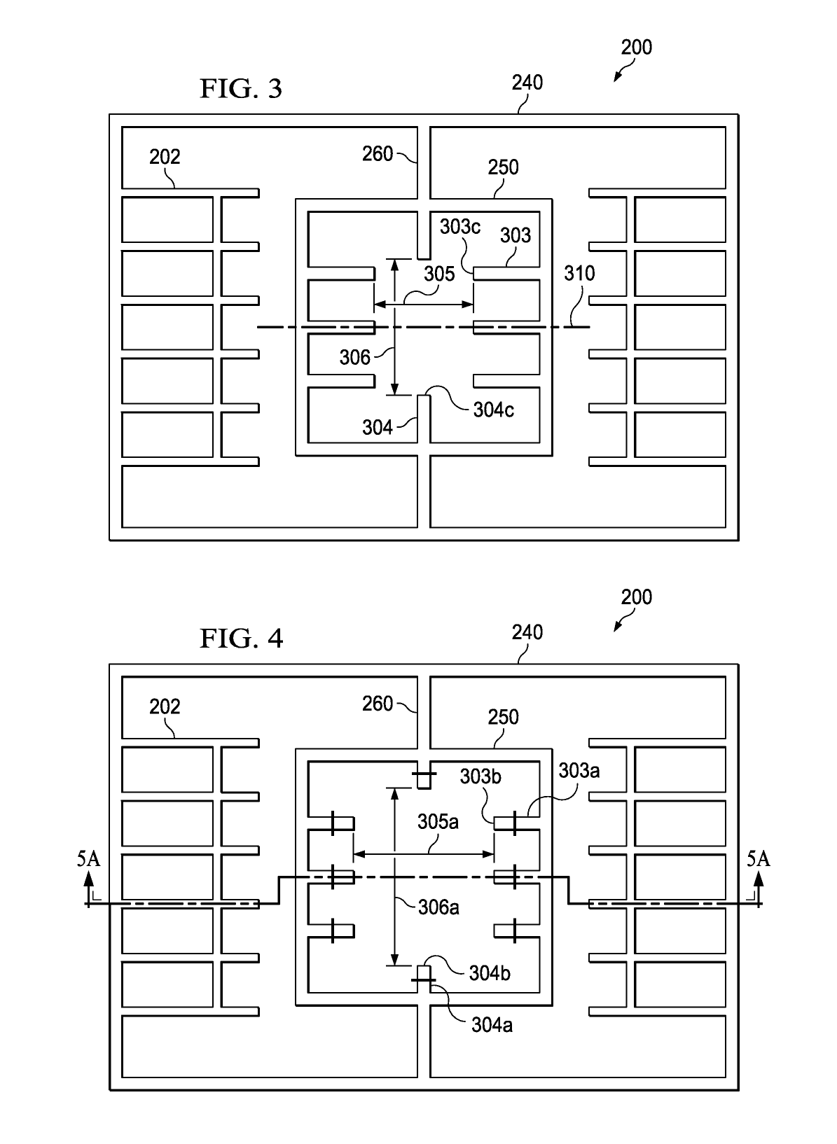

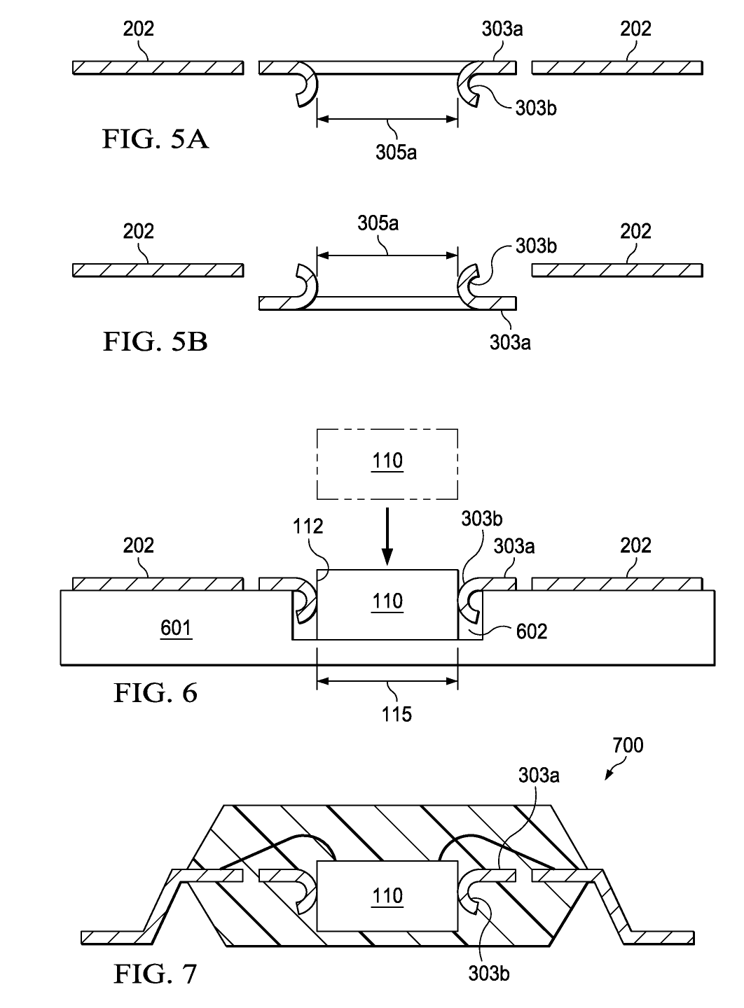

As FIG. 1 shows, leadframe 101 includes a second set of leads 103. The leads of the second set are grouped in pairs relative to chip 110 so that for each pair, the lead on one side of the chip has a partner on the opposite side of chip 110. The leads are extending from opposite directions towards each other, the tip portion of the leads are facing each other, and are spaced apart by a distance operable to secure a semiconductor chip 110 of width 115 between the tips. The cross section of FIG. 1 depicts only a single pair of two leads 103; however, the top view of FIGS. 3, 4, 10, and 11 illustrate the complete second set of leads 103 of the exemplary device 110. As FIG. 1 depicts, each lead 103 of the second set has a flat portion 103a and a curled portion 103b. The flat portions 103a are in a second horizontal plane. In the examples of FIGS. 1 and 5B, the second plane of lead portions 103a is different from the first plane of lead portions 102a; in the examples of FIGS. 5A, 6 and 7, the second plane is the same as the first plane.

The tip portion of leads 103 are curled as springs acting to exert pressure force in the direction of the leads. Each curl 103b preferably forms at least a portion of a circle, and for paired leads, the curls are curved in mirror image relative to each other. In the embodiment of FIG. 12, the curls form an approximate full circle. In the embodiments of FIG. 1, and also of FIGS. 5A, 5B, 6, 7, and 12, the areas of the curls are in a plane normal to the second horizontal plane. However, in other embodiments the curls of the lead pairs may be formed in the second horizontal plane as long as the curls of each pair face each other to act as springs exerting pressure against a chip inserted between the pair of facing curls.

The semiconductor chip 110 in FIG. 1 is a hexahedron with two large-area surfaces 111 on top and bottom of the hexahedron, and four small-area side wall 112 given by the height of the hexahedron. For typical chips of the silicon integrated circuit technology, the surface dimensions are usually on the order of square millimeters, and the height of the sidewalls is only a fraction of a millimeter (in the order of 0.1 mm). By clamping opposite side walls 112 of chip 110 in the distance between the curled tips of paired metal leads 103, the spring forces of the curls exert pressure on the chip side walls and thus secure the chip to the leadframe by friction. Originating from the sawing process to singulate the semiconductor chip from a wafer, the chip side walls are left rough, with silicon surface contours in the nanometer regime. Consequently, the retarding force based on friction is substantial, since it is the product of the force of the applied spring pressure and a material coefficient dominated by the semiconductor surface constitution. Compared to conventional semiconductor devices employing leadframes, device 100 is free of the leadframes' chip attachment pad and an adhesive attachment compound that affixes the chip to the chip attachment pad.

FIGS. 2 to 12 show certain process steps of an embodiment of the invention for fabricating a leadframe to secure a semiconductor chip to the leadframe by friction, and then using this leadframe for fabricating a packaged semiconductor device. For reasons of cost-effective manufacturing, leadframes are preferably formed from strips of flat base metal. As defined herein, the starting material of the leadframe is called the “base metal”, indicating the type of metal. Consequently, the term “base metal” is not to be construed in an electrochemical sense (as in opposition to ‘noble metal’) or in a structural sense.

Whether the leadframe is intended to include cantilevered leads, as shown for leads 102 in FIG. 1 for S-shape or J-shape small outline surface mount devices, or to lack cantilevered leads as in Quad Flat No-Lead (QFN) and Small Outline No-Lead (SON) devices, the base metal is preferred to provide a ductility offering an elongation of at least 5 to 8% in order to satisfy the requirements of lead curling. The metal ductility needed for the curling process is readily provided by the ductility of copper and copper alloy as base metal in the sheet thickness range 100 to 300 μm; thinner sheets are possible. In addition, experience has shown that base metals such as aluminum and aluminum alloys, iron-nickel alloys, and Kovar™ may have suitable ductility with the appropriate sheet thickness and thermal history such as tempering, annealing, and strain hardening.

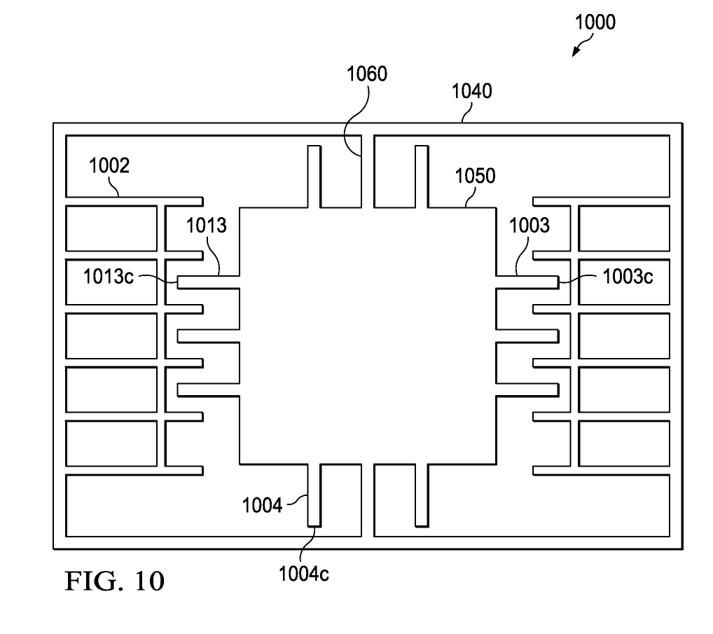

From the original sheet, the desired shape of the leadframe is obtained by an etching or stamping method, preferably by a batch process in strip form. Examples of discrete leadframes are illustrated in FIG. 2 (designated 200) and FIG. 10 (designated 1000). These leadframes include an outer frame (240 and 1040, respectively), an inner or central portion (250 and 1050, respectively), straps (260 and 1060, respectively) connecting the inner portion to the outer frame, and a plurality of segments. In FIG. 2, the segments are represented by the first set of leads 202, and in FIG. 10, the segments are represented by the first set of leads 1002. In the leadframes depicted in FIG. 2 and FIG. 10, the first set leads extend from the outer frame towards the inner portion. In FIG. 10, the second set leads 1003 originate from the inner portion and the lead tips are oriented away from the inner portion.

For many devices, all portions of the leadframe remain in the original horizontal plane of the metal sheet, referred to as the first plane. For other devices, portions of the leadframe, such as the inner or central portion, may be positioned in a different horizontal plane, referred to as the second plane. The transition from the first to the second plane can be accomplished by pressing a step into the metal straps 260, 1060.

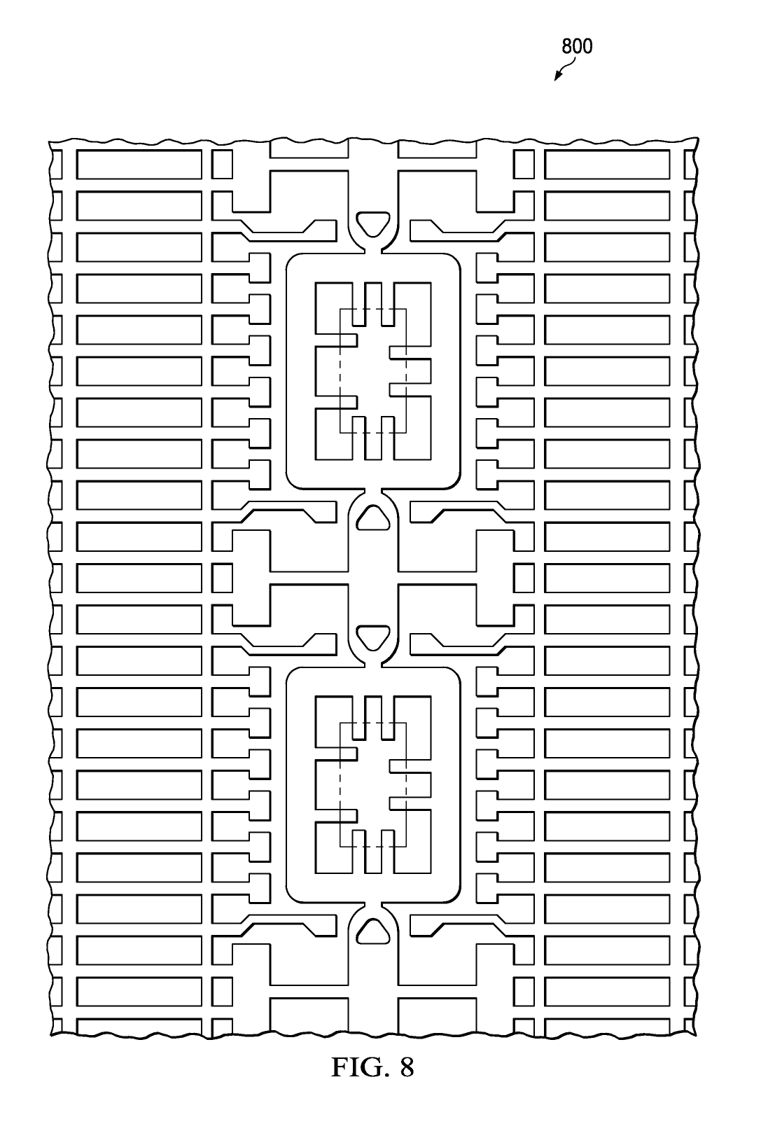

FIG. 3 depicts the inner portion 250 etched or stamped in order to form a second set of leads 303 and 304. The orientation of the leads of subset 304 is normal to the orientation of the leads of subset 303, since these leads are eventually intended to clamp the side walls of a semiconductor chip and the chip sidewalls are normal to each other. As FIG. 3 shows, the second set leads 303 and 304 are positioned on opposite sides of inner portion 250, and are grouped in pairs of opposite direction. The tips 303c of the leads of subset 303 face each other across a gap of distance 305; the tips 304c of paired leads of subset 304 face each other across gap of distance 306, which may be different from distance 305. In the leadframe design of FIG. 3, the lead grouping in pairs follows a straight line of symmetry, exemplified by line 310. In other leadframe designs, such as depicted in FIG. 8, the lead grouping in pairs follows an offset line.

In the next process step, illustrated in FIG. 4, the tips of each pair of leads 303, and each pair of leads 304, are transformed into springs 303b and 304b, respectively, while the remaining flat lead portions are referred to as 303a and 304a, respectively. The springs have the capability to exert pressure force in the direction of the leads; consequently, the springs can secure a semiconductor chip by friction, when such chip is clamped in the newly created distance between two respective curls of a lead pair. To achieve the transformation into springs, the tips of a lead pair are bent so that the bent portions mirror image each other. The bending action is referred to herein as curling, and the bent lead tips are referred to as curls. The spring function of a curl pair can be fulfilled by a variety of different curl shapes. For example, a curl may be a sharp bend of the lead, forming a 90° angle; or a curl may have the shape of at least a portion of a circle; or a curl may be formed as an approximate full circle. If the plane of a lead pair is called the first plane, the plane of the curls may be normal to the first plane, or the plane of the curls may also be in the first plane. After the process of curling, the curls are spaced apart by gaps of a distance enlarged compared to the distance between the original lead tips; gap 305 is enlarged to 305a, and gap 306 is enlarged to 306a. The enlarged distances are determined to be almost, but not quite as large as the lateral dimensions (such as width 115) of the chip hexahedron.

FIGS. 5A and 5B are obtained at the cutaway indicated in FIG. 4 and display a few examples of curl formation, curl shape, and curl position. In FIG. 5A, first set leads 202 are in a first horizontal plane. The remaining flat lead portions 303a are also in the first horizontal plane. The curled lead tips 303b are formed as approximate semicircles, facing each other in mirror image, and oriented “downward” from the flat lead portion 303a. The plane of the curls is normal to the first plane. The leadframe configuration of FIG. 5A is employed for the chip assembly steps described in FIGS. 6 and 7.

In FIG. 5B, first set leads 202 are in a first horizontal plane. The remaining flat lead portions 303a are in a second horizontal plane offset from in the first horizontal plane. A mentioned above, this offset can be achieved by pressing a step into straps 260 during the leadframe formation process. The curled lead tips 303b are formed as approximate semicircles, facing each other in mirror image, and oriented “upward” from the flat lead portion 303a. The plane of the curls is normal to the second and the first plane. The leadframe configuration of FIG. 5A is used for the assembled and packaged device described in FIG. 1.

FIG. 6 displays the next process step of inserting a semiconductor chip 110 into the gap distance 305a between the two lead tip curls 303b of a lead pair. Chip 110 has a width 115, and a length (not shown in FIG. 6). Width 115 is slightly larger than gap 305a, and the length is slightly larger than gap 306a. By inserting slightly larger lateral chip dimensions into the gap dimensions provided between the lead curls, the curls are pressed like springs, which in turn respond by spring force against the inserted chip sides after the insertion process. The difference between chip dimensions and gap dimensions depends on the elastic properties of the lead metal and the amount of curl bending. For support during the operation, the leadframe is placed on a flat pedestal 601, which provides grooves 602 to accommodate the downward-formed lead curls 303b and to stop chip 110 by acting as a barrier in the insertion process. As stated, the spring-like curls 303b press against the sidewalls 112 of the chip, which have been roughened in the sawing process of singulating chip 110 from the original semiconductor wafer. According to COULOMB's law of friction between solid surfaces, the retarding force F_{f} of friction is proportional to the force Fₚ of pressing the two surfaces multiplied by a friction coefficient C dependent on the materials and the surface condition (but not on the surface sizes):

F_{f}=Fₚ·C.

The friction coefficient C increases with surface roughness. While the leadframe and chip are still resting on support 601, the chip terminals are electrically connected to the leads 202, for instance by bonding wires. The leadframe with the clamped and wire-bonded chip is then removed from support 601 and encapsulated, for instance by a transfer molding process using an epoxy-based molding compound. After the encapsulation step, the outer frame 240 is removed by a trimming process, since its support of the individual leads is no longer needed.

FIG. 7 depicts a finished device 700 of the surface mount small-outline family with cantilevered outer leads formed into so-called gull-wings for surface mount assembly to external parts. In contrast to the device 100 of FIG. 1, device 700 uses a leadframe with the curls 303b of opposite lead tips for clamping the chip side walls formed in a downward direction. It should be mentioned that for both embodiments the encapsulation may be designed so that the chip surface opposite to the wire-bonded surface is exposed to the outside, rather than covered by encapsulation compound as shown in FIGS. 7 and 1. Exposed semiconductor surfaces can be soldered directly to heat sinks, thus reducing the path for thermal energy transfer away from the heat-generating chip significantly compared to a device packaged in all-around plastic encapsulation.

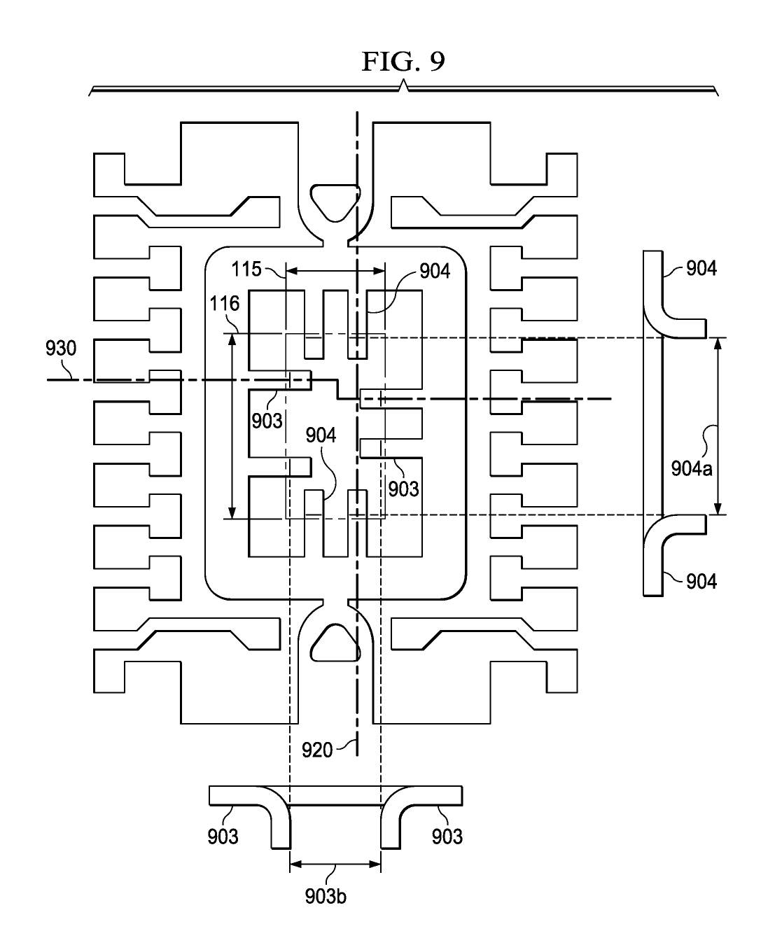

Illustrating another embodiment, FIGS. 8 and 9 depict a production leadframe for a 16-pin surface mount device. The leadframe strip 800 is made from a 125 μm thick copper sheet and is intended for assembling a rectangular silicon integrated circuit chip with a length 116 of 1.85 mm and a width 115 of 1.00 mm (indicated by dashed lines in FIG. 9). As the enlargement of FIG. 9 shows, the 8 leads of the second set are grouped into 4 pairs of 2 leads each, 2 pairs 903 for clamping the side walls of the chip length 116 and 2 pairs 904 for clamping the side walls of the chip width 115. The leads have a width of about 200 μm and a length of about 400 μm for the flat portion. The lead tips of each pair are bent into curls forming about a quarter circle; the two curls of a pair face each other in mirror-image. In order to achieve forceful clamping, the opening 903a between lead pair 903 is slightly smaller than chip width 115 (the exact amount depends on the elastic characteristics of the lead such as selection of metal, thickness, amount of curling); and the opening 904a between lead pair 904 is slightly smaller than chip length 116.

It should be noted that for each pair 904, the leads of opposite direction are aligned along a straight line 920. On the other hand, for each pair 903, the leads of opposite direction are aligned by a line 930 including an offset measuring about a lead width (200 μm). This offset does not introduce any sheer stress into the single crystalline lattice of the semiconductor chip, since it is balanced by the adjacent lead pair, which exhibits an analogous offset in the opposite direction. In general, lead pairs facing each other with a slight and balanced offset helps to avoid lead crowding along the chip dimensions.

FIGS. 10 to 12 show certain process steps of another embodiment of the invention for fabricating a leadframe to secure a semiconductor chip to the leadframe by friction. Starting from an original sheet of base metal, FIG. 10 illustrates the process step of forming a discrete leadframe 1000 by an etching or stamping method to create an outer frame 1040, an inner portion 1050, straps 1060 connecting the inner portion to the outer frame, a plurality of leads 1002 of a first set and a plurality of leads 1003 and 1004 of a second set. Leads 1002 extend from the outer frame 1040 towards the inner portion 1050, and leads 1003 and 1004 originate from the inner portion 1050 and extend towards the outer frame 1040. Leads 1003 and 1004 are grouped in pairs of opposite direction; as an example, leads 1003 and 1013 are a pair. The lead tips 1003c and 1013c of a pair are facing away from each other.

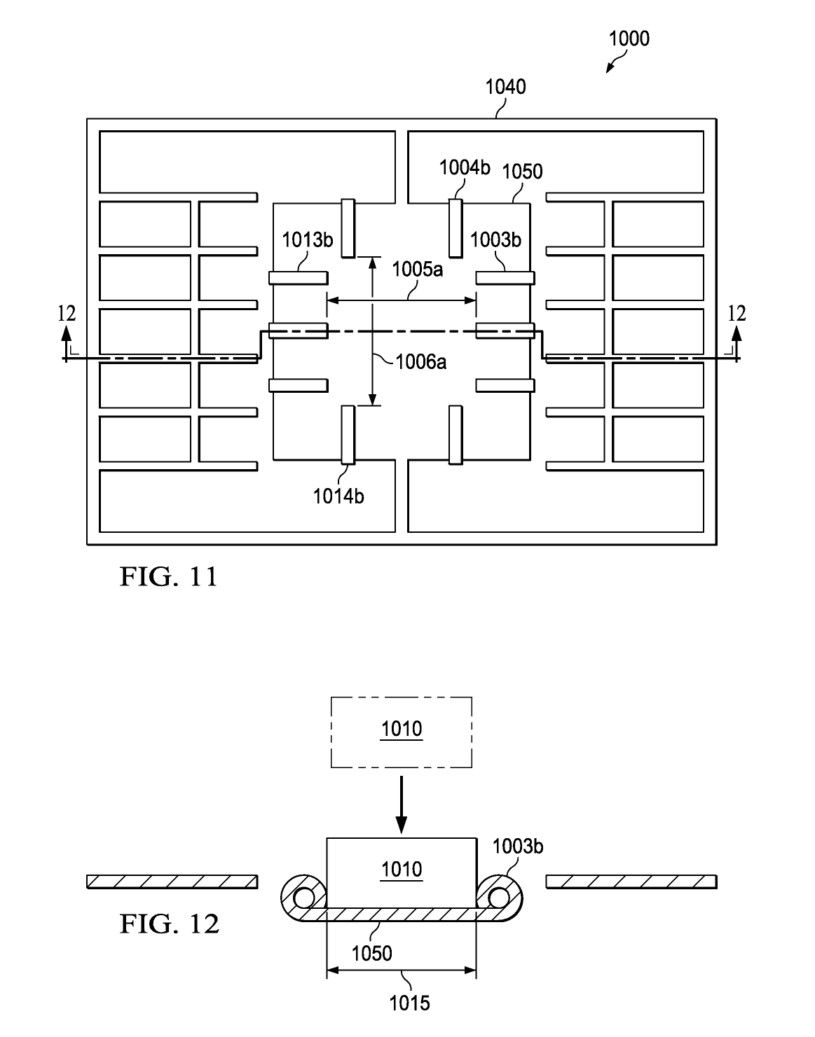

As FIGS. 11 and 12 illustrate, leads 1003 and 1004 are bent in a forming process, slightly elongated, and formed into curls 1003b 1004b of approximately full circles. By way of explanation, an outside force, applied along the length of the leads, can stretch the lead in the direction of the length, while the dimension of the width is only slightly reduced, so that the new shape appears elongated. For elongations small compared to the length, and up to a limit, called the elastic limit given by the materials characteristics, the amount of elongation is linearly proportional to the force. For copper, the limit is about 9% of the starting length. Beyond that elastic limit, the lead would suffer irreversible changes and damage to its inner strength, and would eventually break. Curls 1003b and 1013b are grouped in pairs of opposite direction and face each other to act as springs exerting pressure force in the direction of the leads. The curls of each lead pair are spaced by a distance 1005a or 1006a, respectively, operable to secure a semiconductor chip. If the chip width is designated 1015, then width 1015 should be slightly larger than distance 1005a.

FIG. 12 depicts the package along the offset cutaway indicated in FIG. 11. FIG. 12 shows the inner metal portion 1050 and leads, which are formed in addition to portion 1050 (see FIG. 10; notice contrast to leads 303 and 304, which were subtracted from portion 250). It should be pointed out that a semiconductor chip 1010 with width 1015, when pressed into the slightly smaller distance 1005a, is secured to the leadframe by friction between the curls 1003b and the sidewall surfaces of the chip 1010. Contrary to conventional packages the chip 1050 is not affixed to the inner portion 1050 by an adhesive die-attach material. Because the chip is friction-held to the lead frame by its sidewalls, instead of being glued to the chip pad prior to mold compound encapsulation, the chip in this package does not suffer the thermo-mechanical stress due to CTE mismatch between the chip and the chip pad. Furthermore, the proximity of the chip to the inner portion 1050 greatly enhances heat flow from the chip to the inner metal portion 1050.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the process step of stamping or etching the leadframes from a sheet of base metal may be followed by a process step of selective etching, especially of the second set leads in order to render them more ductile for curling. Another selective etching may be advantageous for exposed base metal surfaces in order to create large-area contoured surfaces for improved adhesion to molding compounds. As another example, the amount of curling and the curvature of bending are flexible and can be adjusted to secure a variety of objects to a leadframe by friction. For instance, instead of a single chip, a multi-chip arrangement can be secured between paired lead curls. It is therefore intended that the appended claims encompass any such modifications or embodiment.

I claim:

1. A metal leadframe comprising two leads extending from opposite directions towards each other, the leads having tip portion curled as springs operable to exert pressure force in the direction of the leads to secure a semiconductor chip therebetween.

2. The leadframe of claim 1 wherein the two leads and the curls are in one plane.

3. The leadframe of claim 1 wherein the two leads are in a first plane and the curls of the lead tips are in a second plane normal to the first plane.

4. The leadframe of claim 1 wherein the curls of the two lead tips form at least a portion of a circle.

5. A semiconductor device comprising:
two leads of a metal leadframe extending from opposite directions towards each other, the leads having tips curled as springs acting to exert pressure force in the direction of the leads, the two curls spaced apart by a distance operable to secure a semiconductor chip; and
a semiconductor chip having sidewalls clamped between the two curls and secured to the leadframe by a friction based on the pressure force.

6. A method for fabricating a leadframe comprising the steps of:
forming leads grouped in pairs on a flat strip of sheet metal; and
curling tip portion of each lead so that the curls of the paired leads face each other operable to exert pressure force in the direction of the leads to secure a semiconductor chip.

7. The method of claim 6 wherein the lead pairs and the curls are in one plane.

8. The method of claim 6 wherein the lead pairs are in the plane of the sheet and the curls of the lead tips are in a plane normal to the plane of the sheet.

9. The method of claim 6 wherein the curls of the lead pairs form at least a portion of a circle.

10. A method for fabricating a semiconductor device comprising the steps of:
providing a leadframe having leads grouped in pairs of opposite direction, each lead pair having the lead tip portion curled so that the curls face each other to operate as springs exerting pressure force in the direction of the leads, the curls of each lead pair spaced apart by a distance and operable to secure a semiconductor chip; and
assembling a semiconductor chip having a width and sidewalls onto the leadframe by inserting the chip width into the distance between the curls of opposite lead tips so that the chip sidewalls are clamped by the curls, securing the chip to the leadframe by the friction based on the pressure force of the curls.
